(19) United States
(12) Patent Application Publication
(10) Pub. No.: US 2024/0118315 A1
(43) Pub. Date: Apr. 11, 2024

(54) CRYOGENIC PROBE CARD

(71) Applicant: Nielson Scientific, LLC, Provo, UT (US)

(72) Inventor: Gregory NIELSON, Lehi, UT (US)

(21) Appl. No.: 18/552,400

(22) PCT Filed: Mar. 23, 2022
(86) PCT No.: PCT/US22/21538

§ 371 Date: Sep. 25, 2023

Related U.S. Application Data
(60) Provisional application No. 63/165,105, filed on Mar. 23, 2021.

(51) Int. Cl. G01R 1/073; G01R 3/00

(52) U.S. Cl. CPC G01R 1/07342; G01R 1/07378; G01R 3/00

(57) ABSTRACT

A probe card comprises a support element that has a first side and a second side opposite the first side. A plurality of probe tips extend outward from the first side of the support element, the probe tips configured to make contact with components of a device-under-test (DUT). A plurality of vias extend through the support element from the first side to the second side, each of the vias connected to a respective probe tip in the plurality of probe tips. A plurality of conductive traces are formed on the support element, and each of the traces is connected to a respective via in the plurality of vias, wherein electrical signals can be provided to or received from the probe tips by way of the conductive traces.

### RELATED APPLICATIONS

This application claims priority to U.S. Provisional Patent Application No. 63/165,105, filed on Mar. 23, 2021 and entitled “CRYOGENIC PROBE CARD,” the entirety of which is incorporated herein by reference.

### STATEMENT OF GOVERNMENTAL INTEREST

This invention was made with Government support under Contract Nos. W909MY-19-P-0032 and W909MY-21-C-0005 awarded by the United States Army. The U.S. Government has certain rights in the invention.

### BACKGROUND

Probe cards are used to test the functionality and connectivity of components of integrated circuits. A probe card can include a plurality of probes that are each configured to make electrical contact with a respective component of an integrated circuit (IC). Functionality or connectivity of the components in electrical contact with the probes can then be tested by way of electrical signals either input to or received from the IC by way of the probes. Conventionally, due to various application and design requirements, probe cards have included probes that are spaced no less than 20 microns apart from one another. Accordingly, conventional probe cards are not well-suited to testing the functionality and connectivity of components of ICs that are spaced closer together than 20 microns.

### SUMMARY

The following is a brief summary of subject matter that is described in greater detail herein. This summary is not intended to be limiting as to the scope of the claims.

Technologies pertaining to a probe card for testing ICs are described herein. With more particularity, a cryogenic probe card that is suitable for testing elements of ICs at low temperatures (e.g., less than or equal to about 0° C., less than or equal to about 200K, or less than or equal to about 150K) is described herein. Still further, a probe card that is suitable for testing elements of an IC that are spaced less than 20 microns apart from one another is described herein.

An exemplary probe card includes a probe platform that includes a support element, a plurality of probe tips, a plurality of vias, and a plurality of conductive traces. The support element can be a substantially solid element that is configured to contain, hold, or otherwise support the probe tips. The probe tips extend outward from a bottom side of the support element. The probe tips are electrically conductive elements that are configured to make contact with a device under test (DUT) to facilitate testing of functionality or electrical connectivity of the DUT. The probe tips can be placed close together on or in the support element. For example, the probe tips can be positioned less than 20 microns apart, less than 10 microns apart, or less than 1 micron apart from one another. The plurality of vias can be configured such that each of the vias is connected to a respective probe tip in the plurality of probe tips. The vias extend from the bottom side of the support element to a top side of the support element. The plurality of conductive traces can be disposed on the top side of the support element and each of the conductive traces connected to a respective via in the plurality of vias. Accordingly, electrical signals can be provided to or received from the probe tips by way of the conductive traces on the top side of the support element.

The support element can include a central platform, a plurality of arms, and an annular portion disposed around the central platform and connected to the central platform by way of the arms. The central platform can include the probe tips mounted thereon/therein. As the probe card is moved toward a face of the DUT, the probe tips make contact with elements on the face of the DUT. The elements of the DUT exert forces on the probe tips in opposition to motion of the probe tips toward the DUT. The support element can be configured to allow the central platform to deflect along a line of motion of the probe card in response to the elements of the DUT exerting force on the probe tips. By way of example, and not limitation, the arms of the central platform can be thin and narrow relative to their length, thereby providing sufficient flexibility to allow the central platform to deflect. The deflection of the central platform that includes the probe tips can prevent the probe tips from damaging the elements of the DUT when the probe tips come into contact with those elements.

The exemplary probe card can further include a circuit board to which the probe platform can be attached. The circuit board can be configured to facilitate handling or mounting of the probe card, or making electrical connections between the probe card and other testing elements, such as any of various electrical meters or measurement devices (e.g., voltmeters, ammeters, ohmmeters, or the like) or electrical sources (e.g., voltage sources or current sources). In exemplary embodiments wherein the support element includes the plurality of arms and/or the annular portion, the probe platform can be attached to the circuit board by way of the arms and/or the annular portion of the probe platform. Each of the plurality of conductive traces of the probe platform can extend to the circuit board and make an electrical connection with a respective electrical contact on the circuit board. The electrical contacts on the circuit board can be configured to facilitate connection of testing elements to the plurality of conductive traces. For example, the electrical contacts can be or include any of various connectors such as coaxial connectors (e.g., BNC connectors), plugs, pins, sockets, or the like.

Some DUTs, such as some types of focal plane arrays (FPAs), are configured to be operated in very cold environments. In order to test functionality of such devices, a probe card must be able to withstand the low temperatures at which these devices operate. The circuit board can further include a plurality of flexures that are configured to permit deflection due to thermal expansion or contraction of the circuit board and/or probe card platform. By way of example, the probe platform can be a substantially planar element. The flexures of the circuit board can be configured to deflect in a direction that is substantially parallel to a plane of the probe platform to reduce mechanical stresses caused by different rates of thermal expansion/contraction between the probe platform and the circuit board. The flexures can further be configured to resist deflection in a direction normal to the plane of the probe platform. For example, the flexures can be configured to oppose deflection of the probe platform caused by forces exerted on the probe pins as the probe pins make contact with the DUT.

The above summary presents a simplified summary in order to provide a basic understanding of some aspects of the systems and/or methods discussed herein. This summary is not an extensive overview of the systems and/or methods discussed herein. It is not intended to identify key/critical elements or to delineate the scope of such systems and/or methods. Its sole purpose is to present some concepts in a simplified form as a prelude to the more detailed description that is presented later.

### BRIEF DESCRIPTION OF THE DRAWINGS

FIG. 1A is a perspective view of a top side of an exemplary probe card.

FIG. 1B is a perspective view of a bottom side of the exemplary probe card shown in FIG. 1A.

FIG. 2A is a perspective view of an exemplary probe card support element.

FIG. 2B is a partial perspective view of the probe card support element shown in FIG. 2A.

FIG. 2C is a partial perspective view of a bottom side of the probe card support element shown in FIGS. 2A and 2B.

FIG. 3 is a head on view of an exemplary platform for supporting probe tips of a probe card.

FIG. 4 is a cross-sectional view of an exemplary support element of a probe card.

FIG. 5 is a partial perspective view of the probe card illustrated in FIGS. 1A and 1B.

FIG. 6 is a cross-sectional view of the probe card illustrated in FIGS. 1A and 1B.

FIG. 7 is a top-down view of another exemplary support element.

FIGS. 8A and 8B are diagrams of exemplary processing steps to form a probe tip support element.

FIG. 9 is a diagram of exemplary processing steps to form another probe tip support element.

FIG. 10 is a flow diagram that illustrates an exemplary methodology for forming a probe card.

### DETAILED DESCRIPTION

Various technologies pertaining to a probe card having closely-spaced probe elements and that is suitable for cryogenic operation are now described with reference to the drawings, wherein like reference numerals are used to refer to like elements throughout. In the following description, for purposes of explanation, numerous specific details are set forth in order to provide a thorough understanding of one or more aspects. It may be evident, however, that such aspect(s) may be practiced without these specific details. In other instances, well-known structures and devices are shown in block diagram form in order to facilitate describing one or more aspects. Further, it is to be understood that functionality that is described as being carried out by certain system components may be performed by multiple components. Similarly, for instance, a component may be configured to perform functionality that is described as being carried out by multiple components.

Moreover, the term “or” is intended to mean an inclusive “or” rather than an exclusive “or.” That is, unless specified otherwise, or clear from the context, the phrase “X employs A or B” is intended to mean any of the natural inclusive permutations. That is, the phrase “X employs A or B” is satisfied by any of the following instances: X employs A; X employs B; or X employs both A and B. In addition, the articles “a” and “an” as used in this application and the appended claims should generally be construed to mean “one or more” unless specified otherwise or clear from the context to be directed to a singular form.

Further, as used herein, the terms “component” and “system” are intended to encompass computer-readable data storage that is configured with computer-executable instructions that cause certain functionality to be performed when executed by a processor. The computer-executable instructions may include a routine, a function, or the like. It is also to be understood that a component or system may be localized on a single device or distributed across several devices. Additionally, as used herein, the term “exemplary” is intended to mean serving as an illustration or example of something, and is not intended to indicate a preference.

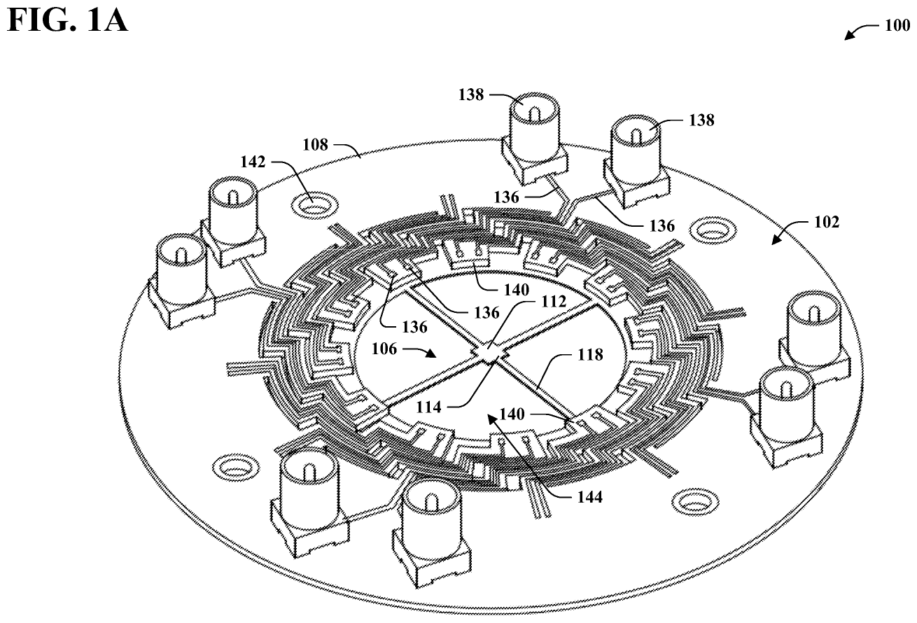

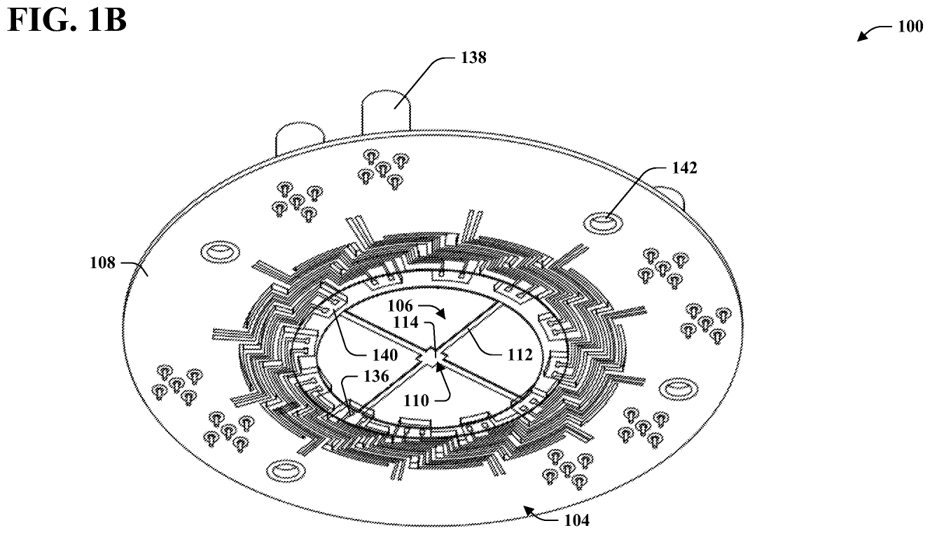

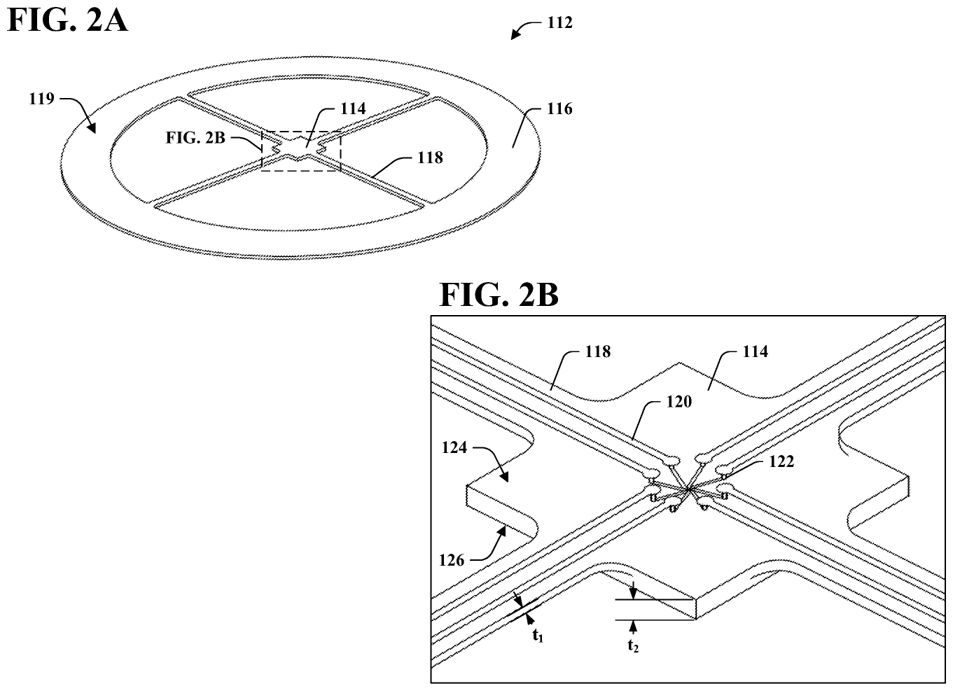

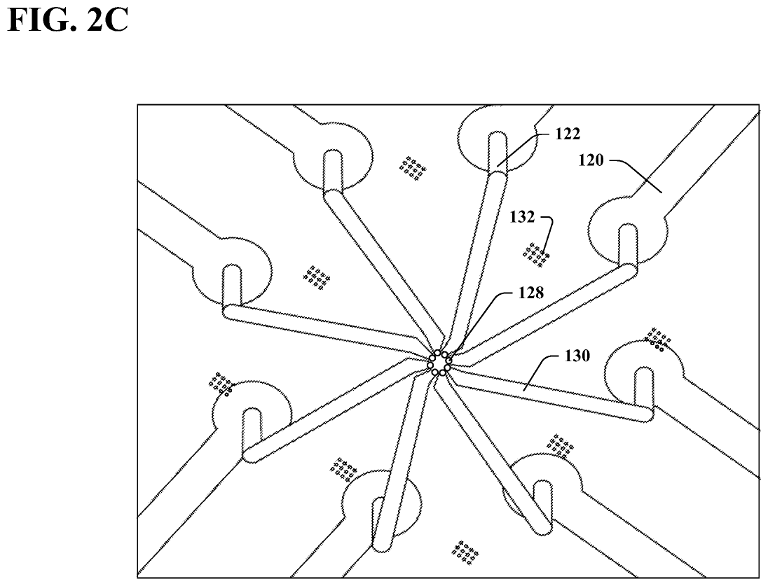

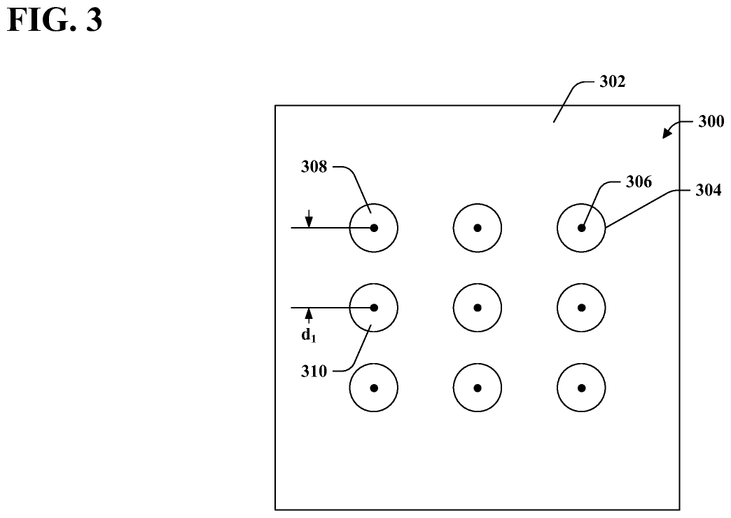

With reference now to FIGS. 1A and 1B, perspective views of an exemplary probe card 100 are illustrated. With reference now solely to FIG. 1A, a perspective view of a top side 102 of the probe card 100 is illustrated. With reference now solely to FIG. 1B, a perspective view of a bottom side 104 of the probe card 100 is illustrated. Referring once again jointly to FIGS. 1A and 1B, the probe card 100 includes a probe platform 106 and a circuit board 108. The probe platform 106 is configured to support a plurality of electrically conductive probes (e.g., depicted in FIG. 2C) according to various embodiments described in greater detail below. The circuit board 108 is configured to support the probe platform 106 and to facilitate making electrical connections between elements of the probe platform 106 and other equipment used with the probe card 100 to test functionality or connectivity of elements on an IC DUT. The circuit board 108 can be, for example, a printed circuit board (PCB) with various components formed thereon or connected thereto.

The probe card 100 can be used to test functionality or connectivity of elements of a DUT by lowering the probe card 100 onto the DUT until probes on an underside 110 of the probe platform 106 make contact with elements of the DUT that are desirably tested. Alternatively, the DUT can be positioned on a stage and raised toward the probe card 100 until the elements of the DUT make contact with the probes on the underside 110 of the probe platform 106.

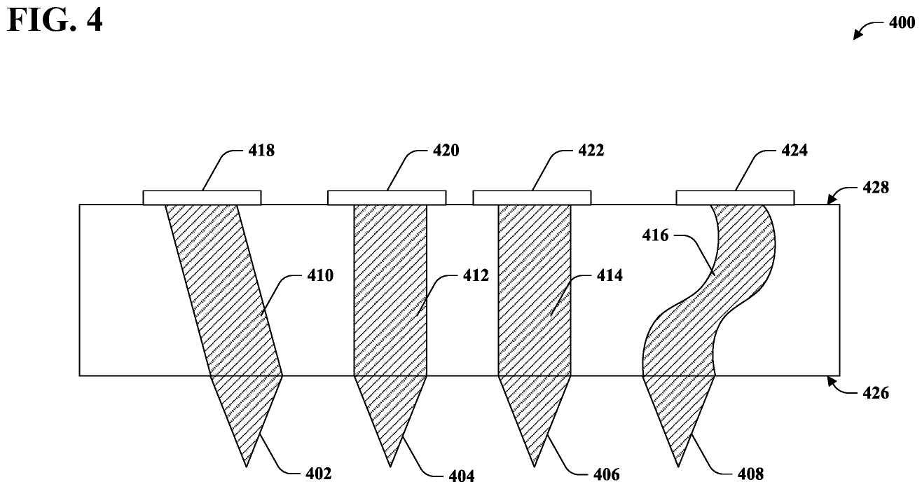

The probe platform 106 includes a support element 112. The support element 112 is configured to support a plurality of electrically conductive probes (e.g., as shown in FIGS. 2C and 3). As will be described in greater detail below, the support element 112 holds the probes in a stable arrangement to facilitate establishment of contact between the probes and elements of a DUT. The support element 112 further contains, supports, or includes various componentry to facilitate the making of electrical connections between testing equipment connected to the probe card 100 and the probes. As used herein, the probe platform 106 is intended to refer to the support element 112 as well as various componentry included thereon/therein.

Referring now to FIGS. 2A-2C, various views of the probe platform 106 are shown. Referring solely to FIG. 2A, a perspective view of the support element 112 is shown. Referring solely to FIG. 2B, a partial perspective view of a central platform 114 of the support element 112 is shown. Referring solely to FIG. 2C, a partial perspective view of an underside of the central platform 114 of the support element 112 is shown.

Referring now once again to FIG. 2A, the support element 112 includes a central platform 114, an annular portion 116, and a plurality of arms 118 that extend from the central platform 114 to the annular portion 116. While not shown in FIG. 2A, the central platform 114 includes the plurality of probes disposed thereon/therein. For example, and referring now briefly to FIG. 3, a view facing an underside 300 of an exemplary central platform 302 is shown, wherein the central platform 302 includes a plurality of probe tips 304 extending therefrom. The central platform 302 is illustrated as including nine probe tips 304, however it is to be understood that substantially any number of probe tips 304 can be included on the central platform 302. The probe tips 304 can have a conical shape extending from the underside 300 of the platform 302 (i.e., out of the page) such that each of the probe tips 304 terminates in a point 306. In other embodiments, the probe tips 304 can have a pyramidal shape.

It is to be understood that the probe tips 304 can occupy only a small portion of the underside 300 of the central platform 302. In other embodiments, the probe tips 304 can distributed across substantially the entirety of the underside 300 of the central platform 302. Furthermore, an arrangement of the probe tips 304 can be based upon an arrangement of elements of a DUT that are desirably tested. For example, if the probe card 100 is intended to be used to test the functionality or connectivity of a DUT with regularly-spaced elements, the probe tips 304 of the central platform 302 can be regularly spaced with a same spacing as the elements of the DUT. In exemplary embodiments, a distance di between a first probe tip 308 in the probe tips 304 and a second probe tip 310 in the probe tips 304 can be less than 20 microns, less than or equal to 10 microns, or less than or equal to 1 micron. In still further embodiments, the distance di can be less than 1 micron, less than or equal to 500 nanometers, or less than or equal to 250 nanometers.

Referring again to FIG. 2A, the support element 112 is configured to permit deflection of the central platform 114 in a direction normal to a surface 119 of the support element 112. Still further, the support element 112 is configured to resist deflection of the central platform 114 along a plane that is parallel to or coplanar with the surface 119 of the support element 112. By way of example, and not limitation, the arms 118 can be thin and narrow relative to their length, such that the arms 118 are stiff in a plane parallel to the surface 119 and capable of deflection in a direction normal to the surface 119. Therefore, when the central platform 114 is subject to upward forces resulting from probe tips on the underside of the central platform 114 contacting a DUT, the central platform 114 is able to exhibit some upward deflection from its initial position. This deflection can prevent contact damage to the DUT being caused by the probe tips. The stiffness of the arms 118 in the plane parallel to the surface 119 prevents the probe tips mounted on the central platform 114 from becoming misaligned with components of the DUT.

Referring now to FIG. 2B, a partial perspective view of the central platform 114 is illustrated. The central platform 114 can have a plurality of conductive traces 120 formed thereon. Each of the conductive traces 120 extends from the central platform 114 and out along a respective arm 118 of the support element 112. The conductive traces 120 can be formed as a layer of metallization on the support element 112 as will be described in greater detail below. Each of the conductive traces 120 is connected to a respective via 122 that extends through the central platform 114 from a top side 124 of the central platform 114 to a bottom side 126 of the central platform 114. Each of the vias 122 is connected to a respective probe tip that extends downward from the bottom surface 126 of the central platform 114. As shown in FIG. 2B, the arms 118 of the support element 112 can be configured to have a thickness ti that is less than a full thickness t 2 of the central platform 114. Therefore, the central platform 114, and the probes disposed thereon, can extend lower than any other part of the probe card 100. This configuration can help to prevent parts of the probe card 100 other than the probes making contact with a DUT when the probe card 100 is moved toward the DUT at an angle offset from a planar surface of the DUT.

Referring now to FIG. 2C, a partial perspective view of the bottom side 126 of the central platform 114 is shown. Elements of the probe platform 106 such as the conductive traces 120 and vias 122 are illustrated for purposes of explanation, but it is to be understood that in some embodiments these features may not be visible from the bottom side 126 of the central platform 114. However, in some embodiments wherein the support platform 112 is formed of a substantially transparent material, the traces 120 and vias 122 may be visible from the bottom side 126 of the central platform 114.

The probe platform 106 includes, on the bottom side 126 of the central platform 114, a plurality of probe tips 128, and a second plurality of conductive traces 130. As will be described in greater detail below, the probe tips 128 can be formed directly on the bottom surface 126 of the central platform 114. In other embodiments, the probe tips 128 can be formed within the bulk of the central platform 114 and subsequently exposed by selective removal of material from the bottom side 126 of the central platform 114 (e.g., by etching, electrical discharge machining, ablation, or the like). The probe tips 128 can be arranged in any configuration suitable for testing components of a DUT. In a non-limiting example, if the DUT is a focal plane array (FPA) having a plurality of light-sensitive pixel cells (LSPCs) disposed thereon, a number and spacing of the probe tips 128 can be configured to align with the plurality of LSPCs such that each of the probe tips 128 makes contact with a respective LSPC of the FPA.

The second plurality of conductive traces 130 can facilitate making connections between the probe tips 128 and the first plurality of conductive traces 120 on the top side 124 of the central platform 114. For instance, when the spacing between the probe tips 128 is small (e.g., less than 20 microns), some manufacturing processes used to form the vias 122 may be unsuitable for forming the vias 122 to be sufficiently small to be positioned directly in line with the probe tips 128. The second conductive traces 130 can fan outward from a cluster of the probe tips 128 to provide greater space for positioning the vias 122.

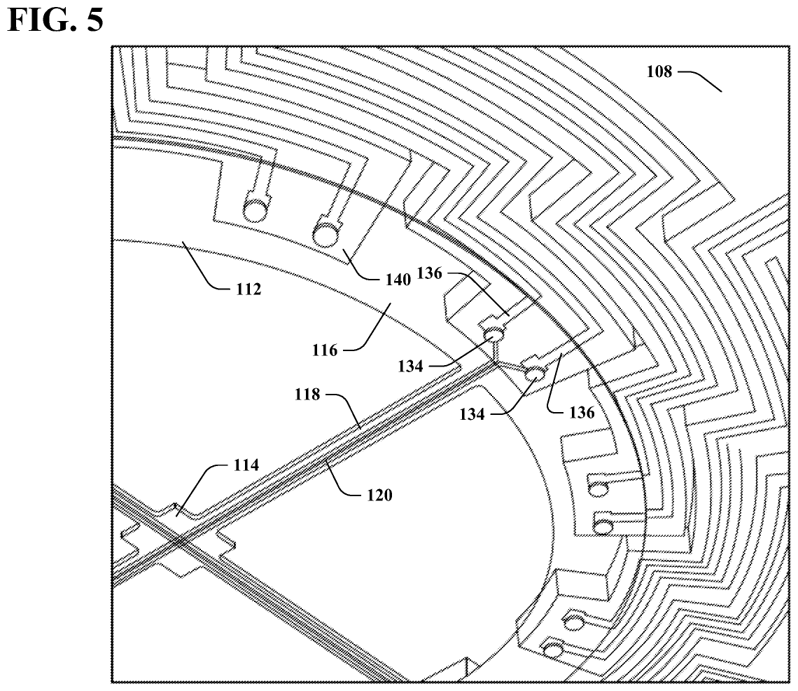

In some embodiments, however, the second plurality of traces 130 are omitted, and the probe tips 128 are connected directly to the conductive traces 120 on the top side 124 of the central platform 114 by way of the vias 122. For example, the vias 122 can be formed by way of multi-photon-absorption-based three-dimensional semiconductor fabrication techniques, such as those described in U.S. patent application Ser. No. 16/498,960. Using such techniques, the vias 122 can be formed to have sufficiently small dimensions to be packed as closely together as the probe tips 128. Referring now to FIG. 4, a cross-sectional view of another exemplary central platform 400 of a probe platform support element is shown. The central platform 400 includes a plurality of probe tips 402-408, a corresponding plurality of vias 410-416, and a plurality of conductive traces 418-424. The probe tips 402-408 extend outward from a bottom side 426 of the central platform 400. The conductive traces 418-424 are formed on a top side 428 of the central platform 400 opposite the bottom side 426 of the platform 400. The vias 410-416 extend directly between the probe tips 402-408 and the conductive traces 418-424, respectively, without additional conductive traces being formed on the bottom side 426 of the platform 400.

Using three-dimensional semiconductor fabrication techniques, the vias 122 can also be formed to be angled with respect to the probe tips 128 and/or the surfaces 124, 126 of the central platform 114. Referring again to FIG. 4, the vias 412, 414 are shown as being substantially vertical and linear vias. In other words, the vias 412, 414 extend directly upward and along a straight line from the probe tips 404, 406, respectively, to the traces 420, 422. By contrast, the via 410, while substantially linear, is angled with respect to the surfaces 426, 428 of the platform 400 and the probe tip 402 to which the via 410 is connected. Still further, the via 416 has a nonlinear, curved shape. Angled and nonlinear vias can be employed to facilitate routing of conductive pathways between the probe tips 128 and the top-side conductive traces 120 in embodiments wherein there are many probe tips that are packed closely together.

Referring once again to FIG. 2C, the central platform 114 can include a plurality of alignment features 132. In some embodiments, the alignment features 132 are disposed on the bottom surface 126 of the central platform 114. In these embodiments, the support element 112, including the central platform 114, can be formed from a material that is substantially transparent to visible wavelengths of light. By way of example, and not limitation, the support element 112 can be formed from silicon carbide, diamond, gallium nitride, sapphire, glass, or other transparent material. In various embodiments, the support element 112 and/or the central platform 114 can have a transmittance of greater than or equal to 50%, greater than or equal to 75%, or greater than or equal to 90% with respect to visible wavelengths of light. In further embodiments, the support element 112 and/or the central platform 114 can have a transmittance of greater than 90%, greater than or equal to 95%, or greater than or equal to 99% with respect to visible wavelengths of light. Transparency of the central platform 114 facilitates alignment of the probe tips 128 with elements of a DUT that are desirably tested. The alignment features 132 can further aid in alignment of the probe tips 128, particularly when the probe tips 128 are small and closely packed. Positioning the alignment features 132 on the same bottom side 126 of the central platform 114 as the probe tips 128 allows the alignment features 132 to be more easily brought into focus by an imaging objective at the same time that the probe tips 128 are brought into focus. In some embodiments, however, the alignment features 132 can be positioned on the top side 124 of the central platform 114.

The alignment features 132 can be formed by any of various means. In non-limiting examples, the alignment features 132 can be formed by selective deposition of materials such as metals or inks. In other examples, the alignment features 132 can be formed by selective removal of material of the central platform 114 such that an alignment feature forms a discernible pattern. For instance, the alignment features 132 can be formed by selective laser ablation, etching, or the like. It is to be understood that while the alignment features 132 are illustrated as arrays of dots, the alignment features 132 can be arranged or configured according to substantially any pattern.

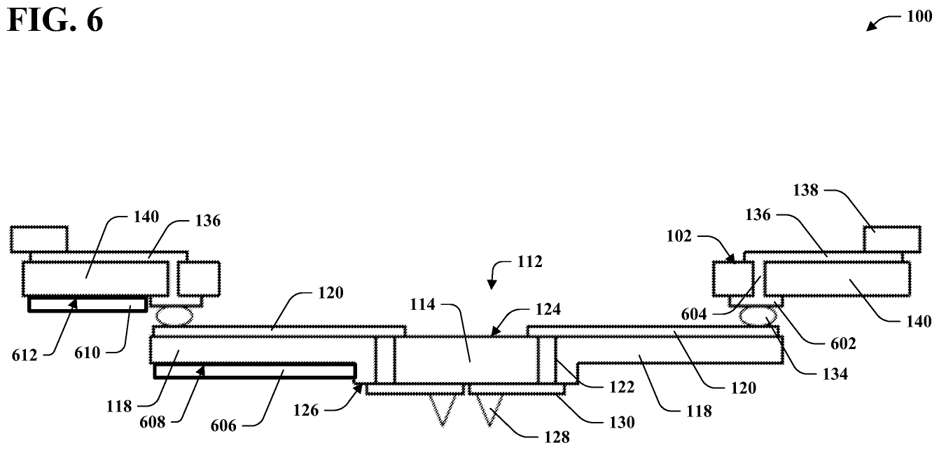

The probe card 100 can include various additional features to facilitate making electrical connections between the probe tips 128 that are held by the support element 112. For example, and referring now to FIG. 5, a partial perspective view of the bottom side 104 of the probe card 100 is shown. The conductive traces 120 are shown and extend along the arms 118 of the support element 112 out to the annular portion 116 of the support element 112. At the annular portion 116 of the support element 112, the conductive traces 120 terminate in electrical contacts 134. In exemplary embodiments, the electrical contacts 134 can be flip-chip bump bonds that are bonded to conductive traces 136 that are formed on the circuit board 108 of the probe card 100. Thus, the electrical contacts 134 can be deposited on a top side of the support element 112 (e.g., the same side of the support element 112 as the top side 124 of the central portion 114). Accordingly, each of the conductive traces 120 on the support element 112 can have a respective electrical contact 134 connected thereto. The traces 120 and corresponding contacts 134 are shown in the bottom-up view of FIG. 5 for the purpose of facilitating explanation. Thus, the traces 120 and corresponding contacts 134, which are positioned on a top side of the support element 112, may not be visible from the bottom side of the support element 112. However it is to be understood that in at least some embodiments the top-side traces 120 and contacts 134 may be visible from the bottom side 104 of the probe card 100 by virtue of transparency of the support element 112 to visible wavelengths of light.

The contacts 134 are electrically connected to traces 136 that are included on the circuit board 108. Referring once again to FIG. 1A, the traces 136 can in turn be connected to connectors 138. It is to be understood, therefore, that each of the connectors 138 can be electrically connected to a different respective probe tip in the probe tips 128. The connectors 138 are configured to allow connections to be made between the probe card 100 and various electrical testing equipment that can be employed to test functionality or connectivity of a DUT. For instance, the connectors 138 are configured to interface with input/output terminals of electrical devices such as voltmeters, ammeters, ohmmeters, current sources, voltage sources, or the like. In exemplary embodiments, the connectors 138 can be or include any of various connectors such as coaxial connectors (e.g., BNC connectors), plugs, pins, sockets, or the like.

In various embodiments, the traces 136 are positioned on the top side 102 of the circuit board 108. In such embodiments, the circuit board 108 can further include a plurality of vias that are configured to connect the traces 136 of the circuit board 108 to the contacts 134 of the support element. It is to be understood, however, that in other embodiments, the traces 136 can be positioned on the bottom side 104 of the circuit board 108, and in these embodiments no additional vias may be necessary.

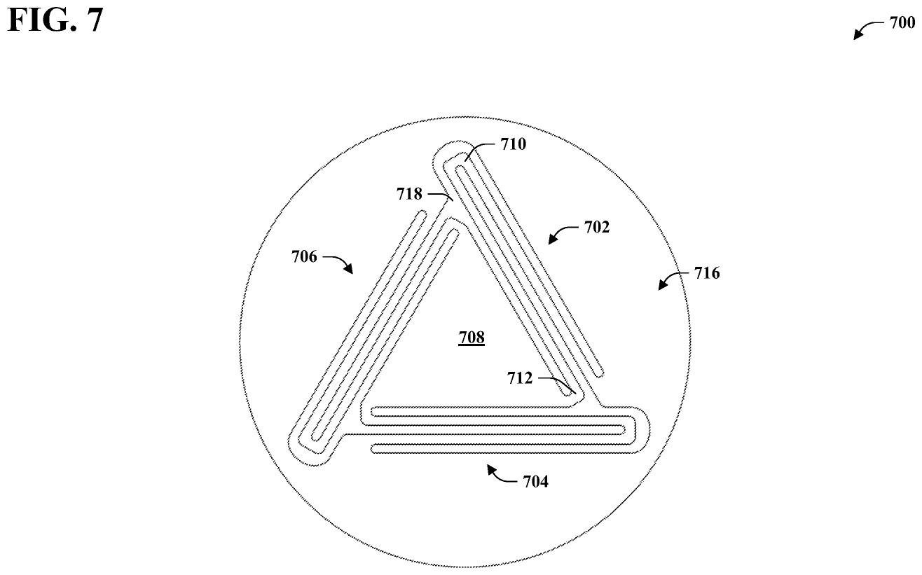

With reference now to FIG. 6, a cross-sectional view of the exemplary probe card 100 is shown. As shown in FIG. 6, the probe tips 128 extend downward from the central platform 114 of the probe card 100. The probe tips 128 are connected to the conductive traces 130 that are formed on the bottom side 126 of the central platform 114. The conductive traces 130 fan out from the probe tips 128, which can be positioned proximally to a center of the center platform 114. The conductive traces 130 can therefore provide sufficient spacing for the vias 122 to be electrically connected to only a single probe tip in the probe tips 128. As noted above, however, in embodiments wherein the vias 122 can be made sufficiently small to avoid any of the vias 122 contacting more than one probe tip 128 (e.g., having a diameter of less than or equal to 10 microns, less than or equal to 5 microns, or less than or equal to 1 micron), the bottom-side conductive traces 130 can be omitted and the vias 122 can be positioned directly above their respective probe tips 128 (e.g., as shown in FIG. 4).

Referring still to FIG. 6, the vias 122 each extend through the central platform 114 from a respective trace in the traces 130 to the top side 124 of the central platform 114. At the top side 124 of the central platform 114, the vias 122 are connected to the top-side conductive traces 120. The top-side conductive traces 120 are electrically connected to the contacts 134 (e.g., bump bonds). The contacts 134 can be connected to corresponding contacts 602 on the bottom side 104 of the circuit board 108. The contacts 602 are in turn connected to vias 604 that extend through the circuit board 108 and make electrical connection between the contacts 602 and the conductive traces 136 on the circuit board 108. The conductive traces 136 are themselves connected to the connectors 138. Thus, each of the probe tips 128 is electrically connected to a respective connector in the connectors 138 by way of the traces, 130, 120, 136, the vias 122, 604, and the contacts 134, 602. In some embodiments, a probe card can be formed by positioning the connectors 138 directly on the support element 112 (e.g., in place of the contacts 134) and omitting the circuit board 108 altogether.

As noted above, some DUTs that are desirably tested by a probe card, such as some types of FPAs, are configured to be operated in very cold environments. In order to test functionality of such devices, a probe card must be able to withstand the cryogenic temperatures at which these devices operate. Furthermore, the probe card must be able to withstand mechanical stresses due to thermal expansion and contraction as the probe card is cooled and/or allowed to return to room temperature.

The probe card 100 can be configured for use in cryogenic environments. In exemplary embodiments, the probe card 100 includes a plurality of flexures. Referring once again to FIG. 1A, the circuit board 108 includes a plurality of flexures 140. The flexures 140 are attached to the support element 112. For example, the flexures 140 can be attached to the support element 112 by way of flip-chip bump bonding (e.g., by way of the contacts 134). In other embodiments, the flexures 140 can be attached to the support element 112 by way of fasteners, adhesives, or other means of attachment. The flexures 140 are configured to provide stiffness that resists motion of the support element 112 in a direction normal to a surface of the circuit board 108 (e.g., the top surface 102). The flexures 140 are further configured to allow expansion and contraction of the support element 112 in a direction parallel to the plane of the surface 102. When the probe card is cooled to very low temperatures from room temperature, different coefficients of thermal expansion of the support element 112 and the circuit board 108 cause the support element 112 and the circuit board 108 to contract at different rates. Likewise, when the probe card 100 is heated to room temperature (e.g., for storage), the support element 112 and the circuit board 108 expand at different rates. The flexures 140 allow the support element 112 to expand/contract at a different rate than the circuit board 108 in a direction parallel to, for example, the top surface 102 of the circuit board 108. As shown in FIGS. 1A, 1B, and 5, the flexures 140 can have a stepped profile. However, it is to be understood that the flexures 140 can have substantially any design that allows the support element 112 to expand laterally (i.e., parallel to the plane of the surface 102) while maintaining electrical contact between the conductive traces 136 are disposed on the flexures 140 such that movement of the flexures 140 alleviates mechanical stresses at points of electrical contact (e.g., the contacts 134) between electrical elements included on the support element 112 and the circuit board 108.

In some embodiments, additional metallization layers can be formed on the support element 112 or the circuit board 108 to provide offsetting mechanical strains to any of various other metallization layers (e.g., the traces 120, 130, 136). For example, and referring once again to FIG. 6, a metallization layer 606 is formed on an underside 608 of the support element 112 along one of the arms 118 of the support element 112. The metallization layer 606 can alleviate mechanical stresses on one of the arms 118 of the support element 112 that are caused by thermal expansion of the support element 112 due to different coefficients of thermal expansion between the conductive traces 120 and the support element 112. Similarly, a metallization layer 610 can be formed on an underside 612 of a flexure in the flexures 140 in order to offset mechanical stress of thermal expansion of the circuit board 108 relative to the conductive traces 136. The metallization layers 606, 610 can be unconnected to any of the electrical components included on the support element 112 or the circuit board 108.

Referring once again to FIGS. 1A and 1B, the circuit board 108 can include mounting holes 142. The mounting holes 142 can be used to mount the probe card 100 to a stage (not shown) that can be used to position the probe card 100 for testing of a DUT.

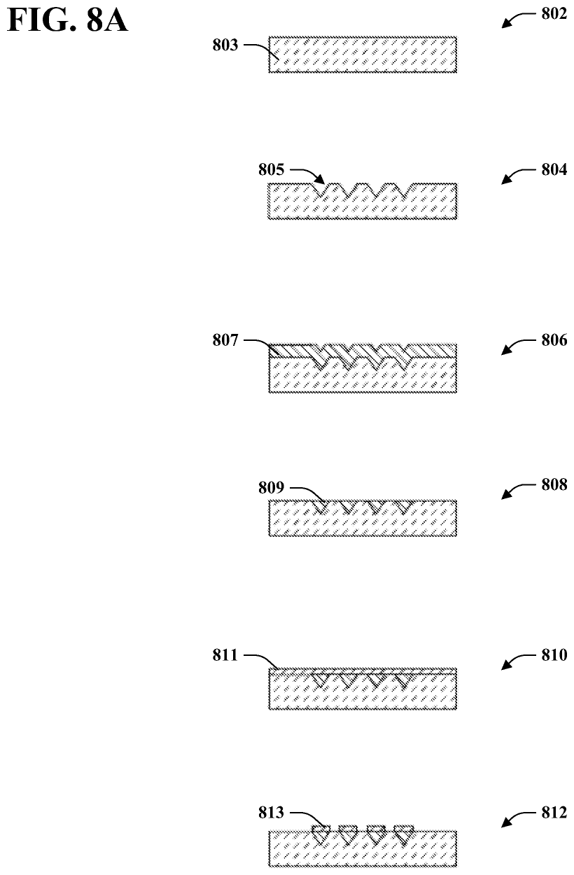

With reference now to FIG. 7, another exemplary support element 700 is shown, wherein the support element 700 includes a plurality of flexures 702-706. The flexures 702-706 are disposed about and connected to a central platform 708 that can have a plurality of probe tips (not shown) formed thereon. The flexures 702-706 can have a switchback profile that is configured to give the central platform 708 compliance in a vertical direction (i.e., into or out of the page) and stiffness in a radial direction (i.e., in the plane of the support element 700). For instance, the flexure 702 includes a switchback arm 710 with a first end 712 and a second end 714. The first end 712 connects to the central platform 708 and the second end 714 connects to an outer portion 716 of the support element 700. The switchback arm 710 is surrounded by a first void 718 and a second void 720 that extend through the support element 700 (e.g., into the page). The first void 718 of the switchback arm 710 partially defines a switchback arm 722 of the flexure 706, whereas the second void 720 of the switchback arm 710 partially defines a switchback arm 724 of the flexure 704.

The support element 112 and/or the support element 700 can be formed as monolithic elements. For example, the support elements 112, 700 can be formed by selective removal of material from a wafer of semiconductor material. In an exemplary embodiment, openings 144 in the support element 112 that are defined by positions of the arms 118 can be formed by etching or diamond grinding material away from a circular planar element (e.g., a wafer of silicon carbide). In other embodiments, the openings 144 can be formed by electrical discharge machining (EDM). In such embodiments, a hole can be formed in a circular planar element by drill or plunge EDM. Subsequently, a conductive wire can be threaded through the formed hole. The conductive wire can be used to form the opening 144 by wire EDM.

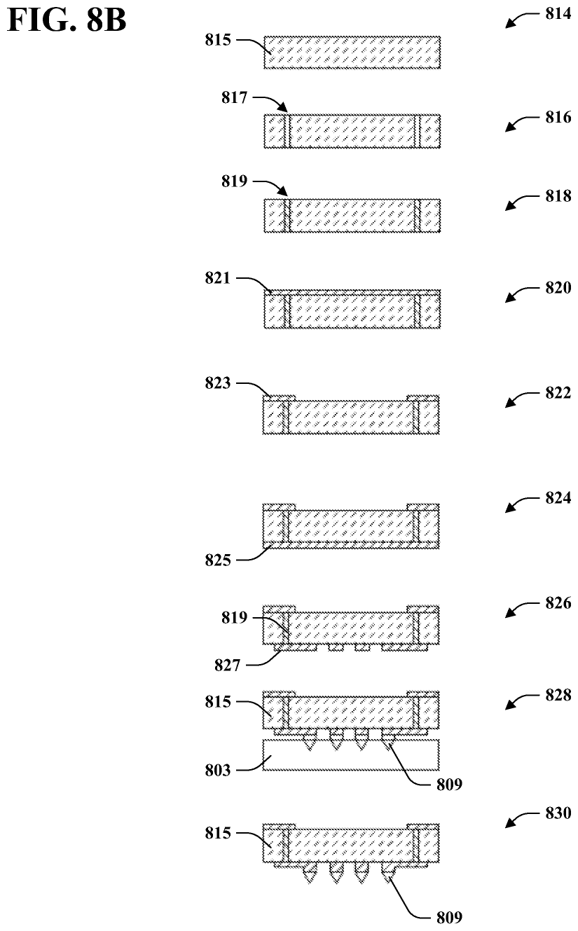

Referring now to FIGS. 8A and 8B, a plurality of processing steps for forming probe tips in a support element are illustrated. While a plurality of processing steps are shown in FIGS. 8A and 8B, it is to be understood that intermediate processing steps between the illustrated steps can be performed. Still further, not all of the illustrated steps may need to be performed to implement the process described herein. Referring now to FIG. 8A, at 802 a silicon wafer 803 is obtained. At 804, a plurality of pyramidal or conical pits 805 are formed in the silicon wafer by way of etching. In exemplary embodiments, the pits can be formed by potassium hydroxide (KOH) etching. In other embodiments, the pits can be formed by a multi-photon-absorption-based etching process. At 806, a metal layer 807 is deposited on the etched wafer 803. The metal layer 807 is deposited such that the metal fills the pits 805. The metal layer 807 can be formed from a material that is desirably used to form probe tips for a probe card. In exemplary embodiments, the metal layer consists of tungsten. At 808 the metal layer 807 a chemical-mechanical polish (CMP) process is used to remove excess metal, leaving molded metal probe tips 809 in the pits 805. At 810, another metal layer 811 is deposited on the wafer 803 and probe tips 809. In exemplary embodiments, the metal layer 811 consists of aluminum. At 812, excess portions of the metal layer 811 not positioned above the probe tips 809 are removed, leaving a layer of metal 813 on each of the probe tips 809.

Referring now to FIG. 8B, at 814 a wafer 815 is obtained. The wafer 815 can be formed from substantially any material that is desirably used to form a supporting element of a probe card. In exemplary embodiments, the wafer 815 comprises silicon carbide. At 816, via holes 817 are etched through the wafer 815. At 818 the via holes 817 are filled with a conductive metal to form vias 819. For example, the via holes 817 can be electroplated with copper to form the vias 819. At 820, a metal layer 821 is applied to the wafer 815. At 822, the metal layer 821 is etched to leave contacts 823 that are in electrical contact with the vias 819. At 824 another metal layer 825 is deposited on a bottom side of the wafer 815. At 826, the metal layer 825 is etched to form traces 827 that will connect the probe tips 809 to the vias 819. At 828, the silicon wafer 803 and the probe tips 109 formed therein are aligned to the traces 827 formed on the second wafer 815, and the wafers bonded together by a metal thermo-compression bonding process. At 830, a remainder of the silicon wafer 803 is etched away, leaving the probe tips 809 extending downward from the second wafer 815.

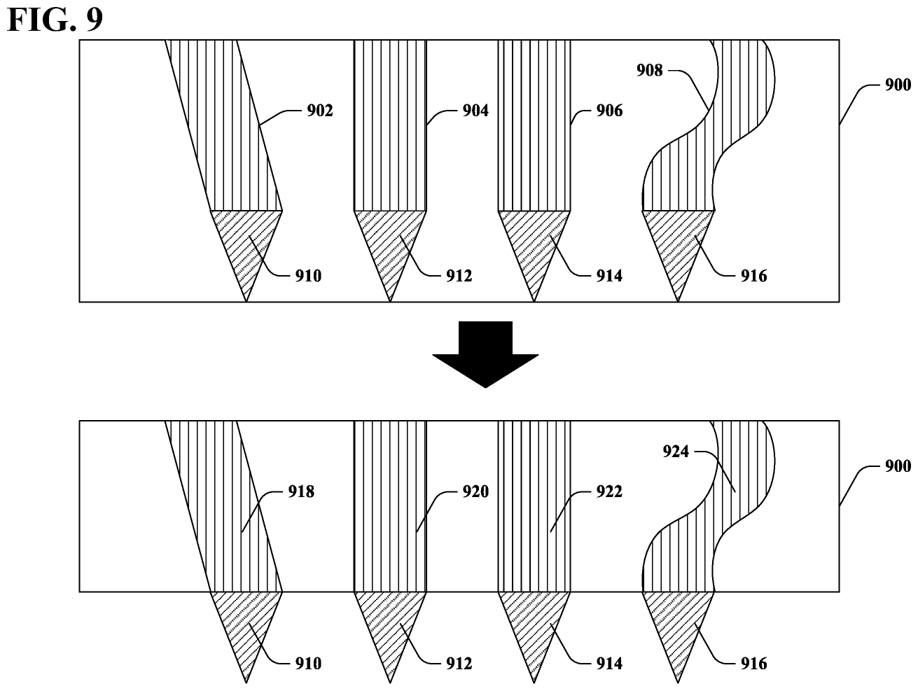

In other embodiments, probe tips can be formed in a support element directly. With reference now to FIG. 9, an exemplary wafer 900 is shown. The wafer 900 can be composed of a material that is desirably used to form a support element for a probe card (e.g., silicon carbide). A plurality of voids 902-908 can be formed in the wafer 900 and filled with conductive materials. In exemplary embodiments, a bottom portion of each of the voids 902-908 can be filled with a first conductive material (e.g., tungsten) to form a plurality of probe tips 910-916. A remainder of each of the voids 902-908 can be filled with a second conductive material (e.g., copper) to form vias 918-924. A bottom portion of the wafer 900 can be etched away to reveal the probe tips 910-916. Conventional semiconductor etching techniques may be unsuitable for forming the voids 902-908 with sufficiently fine pitch (i.e., distance between the voids) to yield a desired pitch of the probe tips. Accordingly, the voids 902-908 can be formed by a multi-photon-absorption-based etching process that is well-suited to forming high-aspect-ratio voids in semiconductors. Formation of the probe tips in the manner described with respect to FIG. 9 may be well-suited to embodiments wherein vias are formed directly above the probe tips in the support element.

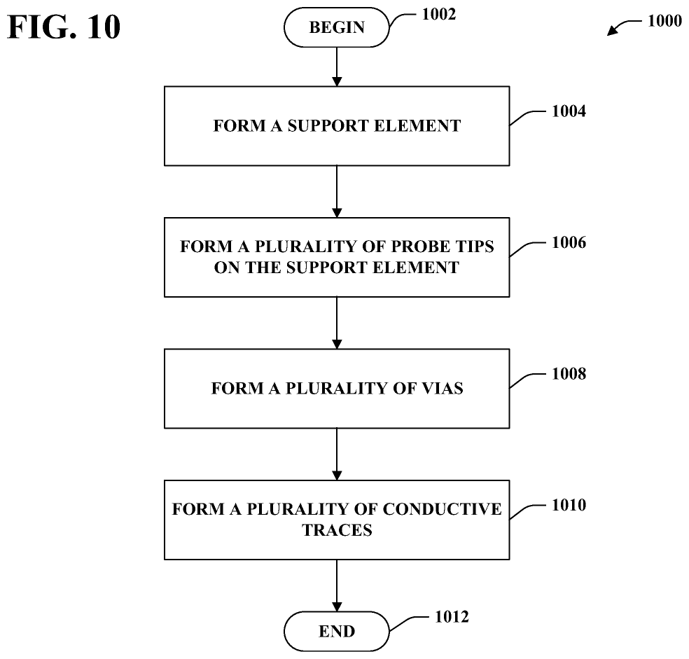

FIG. 10 illustrates an exemplary methodology relating to forming a probe card. While the methodology is shown and described as being a series of acts that are performed in a sequence, it is to be understood and appreciated that the methodology is not limited by the order of the sequence. For example, some acts can occur in a different order than what is described herein. In addition, an act can occur concurrently with another act. Further, in some instances, not all acts may be required to implement a methodology described herein.

Referring now to FIG. 10, a methodology 1000 that facilitates forming a probe card is illustrated. The methodology 1000 begins at 1002, and at 1004 a support element is formed. The support element can be formed such that the support element has a first side and a second side opposite the first side. At 1006 a plurality of probe tips are formed on the support element. The probe tips can be formed such that they extend outward from the first side of the support element. In exemplary embodiments, the probe tips are formed in an arrangement that matches to an arrangement of components on a device that is desirably tested by a probe card. At 1008, a plurality of vias are formed such that the vias extend through the support element from the first side to the second side. Each of the vias is connected to a respective probe tip in the plurality of probe tips. At 1010, a plurality of conductive traces are formed. The conductive traces can be formed on the second side of the support element. Each of the conductive traces can be connected to a respective via in the plurality of vias, such that each of the conductive traces is electrically connected to a single respective probe tip in the plurality of probe tips. The methodology 1000 completes at 1012.

What has been described above includes examples of one or more embodiments. It is, of course, not possible to describe every conceivable modification and alteration of the above devices or methodologies for purposes of describing the aforementioned aspects, but one of ordinary skill in the art can recognize that many further modifications and permutations of various aspects are possible. Accordingly, the described aspects are intended to embrace all such alterations, modifications, and variations that fall within the spirit and scope of the appended claims. Furthermore, to the extent that the term “includes” is used in either the detailed description or the claims, such term is intended to be inclusive in a manner similar to the term “comprising” as “comprising” is interpreted when employed as a transitional word in a claim.

What is claimed is:

1. A probe card, comprising:
a probe platform, the probe platform comprising:
a support element that has a first side and a second side opposite the first side;
a plurality of probe tips extending outward from the first side of the support element, the probe tips configured to make contact with components of a device-under-test (DUT);
a plurality of vias extending through the support element from the first side to the second side, each of the vias connected to a respective probe tip in the plurality of probe tips; and
a plurality of conductive traces, each of the conductive traces connected to a respective via in the plurality of vias, wherein electrical signals can be provided to or received from the probe tips by way of the conductive traces.

2. The probe card of claim 1, the plurality of probe tips including a first probe tip and a second probe tip, the first probe tip and the second probe tip spaced less than 20 microns apart from one another on the support element.

3. The probe card of claim 1, wherein the support element is formed from at least one of silicon carbide, diamond, gallium nitride, sapphire, or glass.

4. The probe card of claim 3, wherein the support element is formed from silicon carbide.

5. The probe card of claim 1, wherein the support element is formed of a material that is substantially transparent to visible light.

6. The probe card of claim 5, wherein the support element has a plurality of alignment features formed thereon.

7. The probe card of claim 6, wherein the alignment features are formed on the first side of the support element and are visible through the support element from the second side of the support element.

8. The probe card of claim 1, wherein the plurality of conductive traces are formed on the second side of the support element, the probe platform further comprising a second plurality of traces disposed on the first side of the support element, wherein the probe tips are connected to the vias by way of the second plurality of traces.

9. The probe card of claim 1, wherein the vias extend vertically through the support element such that each of the vias is aligned with an axis of a respective probe tip in the plurality of probe tips.

10. The probe card of claim 1, wherein each of the vias extends through the support element at an angle relative to an axis of a respective probe tip in the plurality of probe tips.

11. The probe card of claim 1, wherein a first via in the plurality of vias has a nonlinear shape.

12. The probe card of claim 1, further comprising a circuit board, the probe platform attached to the circuit board, the circuit board comprising a plurality of contacts, each of the contacts electrically connected to a respective trace in the plurality of traces.

13. The probe card of claim 12, the circuit board having a plurality of flexures formed therein, the flexures configured to facilitate motion of the probe platform parallel to a plane of the circuit board, the flexures further configured to inhibit motion of the probe platform normal to the plane of the circuit board.

14. The probe card of claim 12, the support element comprising:
a central platform; and
a plurality of arms, the arms extending outward from the central platform, each of the plurality of traces extending along a respective arm in the arms.

15. The probe card of claim 14, the support element further comprising an annular portion disposed about the central platform, the arms extending between the central platform and the annular portion.

16. The probe card of claim 15, wherein the support element is a monolithic element.

17. A method, comprising:
forming a support element that has a first side and a second side opposite the first side;
forming a plurality of probe tips extending outward from the first side of the support element, the probe tips configured to make contact with components of a device-under-test (DUT);
forming a plurality of vias extending through the support element from the first side to the second side, each of the vias connected to a respective probe tip in the plurality of probe tips; and
forming a plurality of conductive traces, each of the conductive traces connected to a respective via in the plurality of vias, wherein electrical signals can be provided to or received from the probe tips by way of the conductive traces.

18. The method of claim 17, further comprising forming a plurality of voids in the support element using a multi-photon-absorption-based semiconductor fabrication technique, wherein forming the plurality of vias comprises filling a first portion of each of the plurality of voids with a conductive material.

19. The method of claim 18, wherein forming the plurality of probe tips comprises filling a second portion of each of the plurality of voids with a conductive material.

20. A system comprising:
a probe platform, the probe platform comprising:
a support element that has a first side and a second side opposite the first side;
a plurality of probe tips extending outward from the first side of the support element, the probe tips configured to make contact with components of a device-under-test (DUT);
a plurality of vias extending through the support element from the first side to the second side, each of the vias connected to a respective probe tip in the plurality of probe tips;
a plurality of conductive traces, each of the conductive traces connected to a respective via in the plurality of vias, wherein electrical signals can be provided to or received from the probe tips by way of the conductive traces; and
a circuit board, the probe platform attached to the circuit board, the circuit board comprising a plurality of contacts, each of the contacts electrically connected to a respective trace in the plurality of traces.
